(19) United States
(12) Patent Application Publication
(10) Pub. No.: US 2009/0220041 A1
(43) Pub. Date: Sep. 3, 2009

(54) SHIFT REGISTER CIRCUIT AND DISPLAY DEVICE

(76) Inventors: Koichi Miwa, Yokohama-shi (JP); Yuichi Maekawa, Kanagawa (JP)

Correspondence Address: Raymond L. Owens;Patent Legal Staff, Eastman Kodak Company, 343 State Street, Rochester, NY, 14650-2201, US

(21) Appl. No.: 12/371,643

(22) Filed: Feb. 16, 2009

(30) Foreign Application Priority Data
Feb. 29, 2008 (JP) 2008-050287

(51) Int. Cl. G11C 19/00

(52) U.S. Cl. 377/79; 377/78

(57) ABSTRACT

A shift register circuit can be manufactured in a simple manner. A shift register circuit is composed of a plurality of cascade-connected latch circuits that latch an input signal in synchronization with a clock signal and output a resultant signal. Two input signals IN and /IN having phases inverted relative to each other are input to each latch circuit, which latches the input signals IN and /IN in synchronization with a clock signal CLK input to a control input, and outputs latched inverted and non-inverted signals /OUT and OUT.

### CROSS-REFERENCE TO RELATED APPLICATION

This application claims priority of Japanese Patent Application No. 2008-050287 filed Feb. 29, 2008 which is incorporated herein by reference in its entirety.

### FIELD OF THE INVENTION

The present invention relates to a shift register circuit and a display device in which a shift register circuit is used.

### BACKGROUND OF THE INVENTION

A structure in which a drive circuit such as a shift register is formed on a flat panel display substrate can eliminate the need to form the drive circuit outside the display substrate, so that the number of external electronic components and the number of interface signal lines can be reduced and cost reduction can be achieved.

Here, a shift register is normally formed of clocked inverters which are cascade-connected, and two external complementary clock signals are alternately input to a clock input of the cascade-connected inverters. The clocked inverters are often formed by using CMOS, of which the two circuit structures that will be described below are mainly known.

In one circuit structure, a PMOS gate to which an inverted clock is connected is inserted between a CMOS inverter and a positive power source, and a NMOS gate to which a non-inverted clock is connected is inserted between the CMOS inverter and a negative power source. In the other circuit structure, a pass gate circuit is serially connected to an input or an output of a CMOS inverter which is connected between positive and negative power sources, and a non-inverted clock is input to a NMOS gate of the pass gate circuit and an inverted clock is input to a PMOS gate of the pass gate circuit. Here, in order to achieve retention of a state during a period for awaiting an input, a clocked inverter which inverts an output and returns the inverted output to the input side can be added between an input and an output of the clocked inverters forming a shift register.

On the other hand, there is a demand for a flat panel display substrate to be formed only of PMOS transistors or only of NMOS transistors from the viewpoint of costs. In order to meet this demand, it is necessary to form a shift register only of PMOS transistors or NMOS transistors. Heretofore, some shift register circuits which operate only with PMOS transistors or NMOS transistors have been proposed.

A simple method for achieving the above demand would be replacing the inverter section of a CMOS shift register with an inverter which is formed only of PMOS transistors to realize a shift register. Conventionally, a structure in which NMOS transistors of a CMOS inverter are replaced with a PMOS gated diode load has been proposed as a PMOS inverter, for example. This example structure, however, has a problem that when an input is at Low level, a through current flows between the positive and negative power sources via the transistors and the gated diode, causing an increase in power consumption.

Various other inverter circuits have also been conventionally proposed in order to overcome the above problem. U.S. Patent Application Publication No. 2007/0220330A1, for example, proposes a structure in which, at a time when an input transistor of a diode load type PMOS inverter is electrically connected, the level of a clock signal connected to a drain of the input transistor is increased to High level, to thereby prevent the through current from flowing through a gated diode.

U.S. Patent Application Publication No. 2007/0103389A1 proposes the following structure of a shift register. Specifically, as an inverter for driving a PMOS transistor in the output stage, an inverter in which an NMOS transistor of a CMOS inverter is replaced with a PMOS transistor, a power source of the CMOS inverter is replaced with a inverted clock, and an inverted clock signal is also input to a gate input of the substituted PMOS transistor is provided. In addition, in place of the NMOS transistor in the output stage, a PMOS transistor having a gate connected to an input of the inverter and a source connected to an output of the inverter, and having a drain to which an inverted clock signal is input is adopted. With this structure, a circuit which achieves bootstrap of the output terminal to High level due to gate-source capacitance of the PMOS transistor provided in place of the NMOS transistor in the output stage is used for forming the shift register.

In the example conventional structures described above, however, as a clock signal directly drives the transistors in the output stage and the output load of a shift register, it is necessary to note the current capacity and delay time of a clock signal.

### SUMMARY OF THE INVENTION

In accordance with one aspect of the invention, there is provided a shift register circuit comprising a plurality of latch circuits which are cascade-connected for latching an input signal in synchronization with a clock signal and outputting an output signal, in which an inverted signal and a non-inverted signal, that are two input signals having phases inverted relative to each other, are input to each of the latch circuits, the latch circuit latching an input inverted signal and an input non-inverted signal in synchronization with a clock signal input to a control input thereof and outputting a latched inverted signal and a latched non-inverted signal.

Preferably, an inverted signal and a non-inverted signal that are input signals are input to a latch circuit in the first stage, and in each of the latch circuits in the subsequent stages which are cascade-connected, an inverted output signal from the latch circuit in the previous stage is input to a non-inverted input and a non-inverted output signal from the latch circuit in the previous stage is input to an inverted input, and two clock signals having different phases are alternately input to the control input of the latch circuits which are cascade-connected.

Preferably, the latch circuit includes a pass gate circuit which transmits or blocks an input inverted signal and an input non-inverted signal in synchronization with a clock signal input to a control input terminal, and a 2-input-2-output inverter circuit which receives, as two input signals, a latched inverted signal and a latched non-inverted signal output from the pass gate circuit and outputs two signals that are a non-inverted signal and an inverted signal.

Preferably, the latch circuit includes a pass gate circuit which transmits or blocks an input inverted signal and an input non-inverted signal in synchronization with a clock signal input to a control input terminal, a first 2-input-2-output inverter circuit which receives, as input signals, two signals that are a latched inverted signal and a latched non-inverted signals output from the pass gate circuit and outputs two signals that are a non-inverted signal and an inverted signal, and a second 2-input 2-output inverter circuit having an inverted output and a non-inverted output connected to an inverted input and a non-inverted input of the first 2-input 2-output inverter circuit, respectively, and a non-inverted input and an inverted input connected to an inverted output and a non-inverted output of the first 2-input 2-output inverter circuit, respectively, and wherein a double positive feedback loop with regard to the inverted and non-inverted signals is formed within the latch circuit.

Preferably, the 2-input 2-output inverter circuit includes at least two 2-input 1-output inverters which receive an inverted signal and a non-inverted signal as input signals and output an inverted signal, and a latched non-inverted signal is input to an inverted input terminal of a first 2-input 1-output inverter, a latched inverted signal is input to a non-inverted input terminal of a second 2-input 1-output inverter, a signal having an identical phase with that of the latched inverted signal is input to a non-inverted input terminal of the first 2-input 1-output inverter, and a signal having an identical phase with that of the latched non-inverted signal is input to a non-inverted input terminal of the second 2-input 1-output inverter.

Preferably, the signal having an identical phase with that of the latched inverted signal which is input to the first 2-input 1-output inverter is an inverted output signal of the second 2-input 1-output inverter, or the signal having an identical phase with that of the latched non-inverted signal which is input to the second 2-input 1-output inverter is an inverted output signal of the first 2-input 1-output inverter.

Preferably, the signal having an identical phase with that of the latched inverted signal which is input to the first 2-input 1-output inverter is an inverted output signal of the second 2-input 1-output inverter, and the signal having an identical phase with that of the latched non-inverted signal which is input to the second 2-input 1-output inverter is an inverted output signal of the first 2-input 1-output inverter.

Preferably, the pass gate circuit is a pass transistor having a gate terminal as a control clock input and a drain terminal and a source terminal connected to a signal input and a signal output, respectively.

Preferably, the pass gate circuit is a transistor having a gate terminal as a signal input and a drain terminal and a source terminal connected to a clock input and a signal output, respectively.

Preferably, the 2-input 1-output inverter includes a first transistor having a gate connected to a non-inverted input, and a drain and a source connected to a first power source and an inverted output, respectively, and a second transistor having a gate connected to an inverted input, and a drain and a source connected to a second power source and an inverted output, respectively.

Preferably, the transistors forming the pass gate circuit and the 2-input 1-output inverter circuit are either only P-type TFTs or only N-type TFTs.

Preferably, the shift register circuit is configured such that the following conditions are satisfied:

1.5*(WL)L1<(WL)M2, and

1.5*(WL)L2<(WL)M4,

and such that the following conditions are satisfied:

(WL)M2<750*(WL)L1, or

(WL)M4<750*(WL)L2,

wherein M2 and M4 are the second transistors of the two 2-input 1-output inverter circuits, respectively, L1 and L2 are two transistors forming the pass gate circuit, and (WL)Mi and (WL)Li are channel areas of Mi (i=2, 4) and Lj(j=1, 2), respectively.

Further, the present invention concerns a display device in which the shift register circuit described above is utilized.

As described above, according to the present invention, a shift register can be composed by utilizing latch circuits. Accordingly, it is possible to form a shift register circuit only of PMOS transistors or only of NMOS transistors.

### BRIEF DESCRIPTION OF THE DRAWINGS

A preferred embodiment of the present invention will be described in detail based on the following figures, wherein:

FIG. 1A is a diagram showing a structure of a shift register circuit according to an embodiment of the present invention;

FIG. 1B is a diagram showing a structure of a latch circuit;

FIG. 2 is a chart showing a shift register operation waveform according to the embodiment of the present invention;

FIG. 3A is a diagram showing an example structure of a latch circuit according to the embodiment of the present invention;

FIG. 3B is a diagram showing a structure of an inverter;

FIG. 4A is a diagram showing an example structure of a latch circuit;

FIG. 4B a diagram showing an example structure in which latch circuits are connected in a plurality of stages;

FIG. 5 is a diagram showing another example structure of a latch circuit according to the embodiment of the present invention;

FIG. 6 is a diagram showing an example circuit structure of a latch circuit according to the embodiment of the present invention;

FIG. 7 is a diagram showing another example circuit structure of a latch circuit according to the embodiment of the present invention;

FIG. 8 is a diagram showing another example circuit structure of a latch circuit according to the embodiment of the present invention;

FIG. 9A is a diagram showing a structure of a pass gate circuit;

FIG. 9B is a diagram showing a structure of a 2-input 1-output inverter;

FIG. 10A is a diagram showing another example circuit structure of a latch circuit according to the embodiment of the present invention;

FIG. 10B is a diagram showing another example circuit structure of a latch circuit according to the embodiment of the present invention;

FIG. 11 is a diagram showing a structure of a display device;

FIG. 12A is a diagram showing an example structure of a latch circuit in which a capacitor is added; and

FIG. 12B is a chart showing a signal waveform in each section.

### DETAILED DESCRIPTION OF THE INVENTION

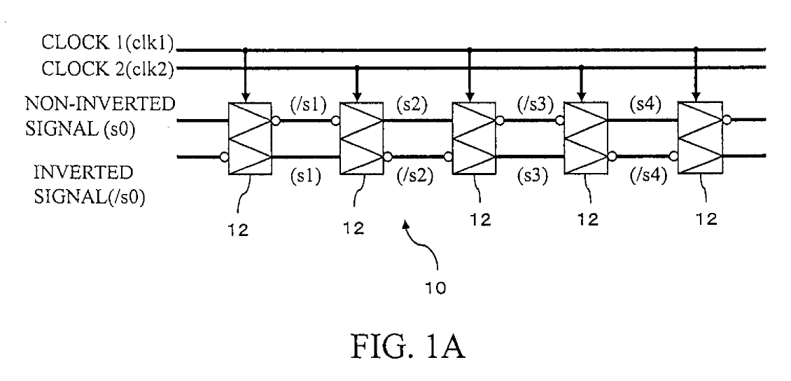

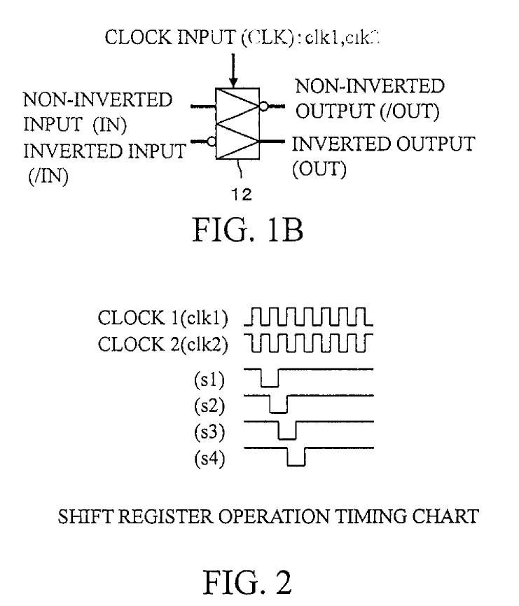

A shift register according to a preferred embodiment of the present invention will be described with reference to the accompanying drawings. FIG. 1A shows a structure of a shift register 10 according to an embodiment of the present invention.

As shown in FIG. 1A, in the present embodiment, the shift register 10 is composed of a plurality of latch circuits 12 which are cascade-connected. A latch circuit 12-1 in the first stage is formed of a 2-input 2-output clocked inverter (2-2cINV) which latches an input signal (s0) and an inverted signal thereof (/s0) in synchronization with a clock having a first phase (clk1) and outputs a non-inverted output signal (s1) and an inverted output signal thereof (/s1). A latch circuit 12-2 in the second stage, receiving the non-inverted output signal from the first stage at a non-inverted input thereof and receiving the inverted output signal from the first stage at an inverted input thereof, latches these input signals in synchronization with a clock having a second phase (clk2) and outputs a non-inverted output signal (s2) and an inverted output signal (/s2). In the subsequent stages, each latch circuit 12 similarly receives the non-inverted output signal from the previous stage at a non-inverted input thereof, receives the inverted output signal from the previous stage at an inverted input thereof, and outputs a non-inverted output signal (si) and an inverted output signal (/si), wherein i represents the stage number of the latch circuit. Further, as a clock (CLK), a clock having a first phase (clk1) is supplied to a control input of the latch circuit 12 in an odd-number stage and a clock having a second phase (clk2) is supplied to a control input of the latch circuit 12 in an even-number stage. In other words, the clock signal 1 (clk1) and the clock signal 2 (clk2) having phases different from each other are alternately supplied to the cascade-connected latch circuits 12. More specifically, the clock having the first phase (clk1) and the clock having the second phase (clk2) have phases which are opposite with respect to each other.

FIG. 1B shows one latch circuit 12 formed of a 2-input 2-output type clocked inverter (2-2cIVT). As shown, the latch circuit 12, in accordance with a clock supplied to a control input terminal thereof, latches signals supplied at a non-inverted input (IN) and an inverted input (/IN) and outputs the resultant signals from an inverted output (/OUT) and a non-inverted output (OUT), respectively. In the drawings, the symbol o represents inversion. Thus, the inverted input (/IN) inverts and latches an input signal, and the inverted output (/OUT) inverts the latched signal and outputs the inverted signal.

FIG. 2 shows a driving waveform of the circuit shown in FIG. 1. It can be understood that an input signal (s0) is sequentially transmitted to the latch circuit 12 in the following stage one by one in accordance with the clock clk1, clk2, and signals s1, s2, s3, and s4 are sequentially output from the respective latch circuits 12, whereby the circuit operates as a shift register.

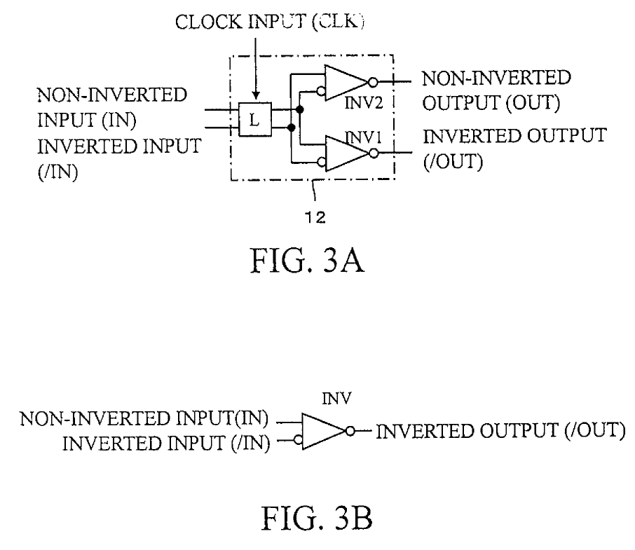

Here, the latch circuit 12 formed of the 2-input 2-output type clocked inverter (2-2cIVT) shown in FIG. 1B can be formed by using a pass gate circuit (L) and two 2-input 1-output type inverters (2-1INV) each outputting an inverted signal with respect to an inverted input signal and a non-inverted input signal. FIG. 3B shows a structure of a 2-input 1-output type inverter (2-1INV), which includes two inputs, that are a non-inverted input (IN) and an inverted input (/IN), and one inverted output (/OUT).

In the example structure shown in FIG. 3A, two inputs, that are a non-inverted input (IN) and an inverted input (/IN), are connected to the pass gate circuit (L). A non-inverted output of the pass gate circuit (L) is connected to a non-inverted input of an inverter INV1 and to an inverted input of an inverter INV2. Further, an inverted output of the pass gate circuit (L) is connected to an inverted input of the inverter INV1 and to a non-inverted input of the inverter INV2. As each of the inverters INV1 and INV2 has one inverted output, the output of the inverter INV1 serves as an inverted output (/OUT) and the output of the inverter INV2 serves as a non-inverted output (OUT).

The operation of the latch circuit 12 shown in FIG. 3A will be described. When the pass gate circuit (L) latches two non-inverted and inverted input signals, a non-inverted signal is input to the non-inverted input terminal of the inverter INV1 and an inverted signal is input to the inverted input terminal of the inverter INV1, and an inverted signal is output from an inverted output terminal of the inverter INV1. Similarly, inverted and non-inverted signals are input to non-inverted and inverted input terminals of the inverter INV2, respectively, and a non-inverted signal is output at an inverted output terminal of the inverter INV2. By using the inverted output of the inverter INV1 as an inverted output terminal and using the inverted output of the inverter INV2 as a non-inverted output terminal, a 2-input 2-output clocked inverter (2-2cINV) can be formed.

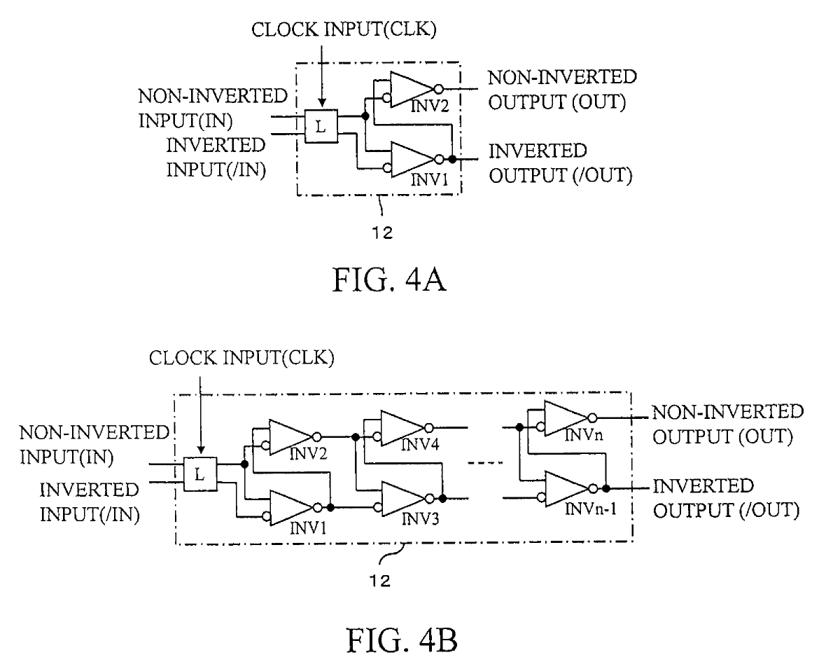

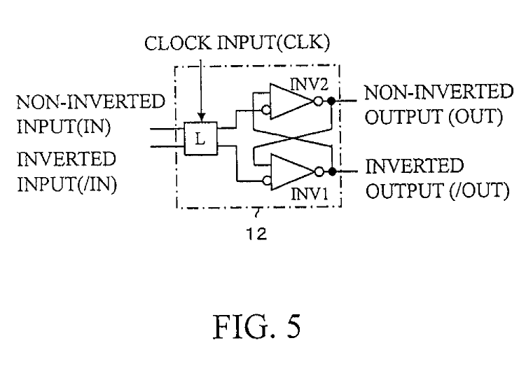

FIGS. 4A and 5 similarly show structures of 2-input 2-output clocked inverters (2-2cINV).

In the example structure shown in FIG. 4A, an inverted output from a pass gate circuit (L) is connected to an inverted input of an inverter INV1 and a non-inverted output from the pass gate circuit (L) is connected to a non-inverted input of the inverter INV1 and an inverted input of an inverter INV2. An inverted output of the inverter INV1 is connected to a non-inverted input of the inverter INV2.

Accordingly, a non-inverted output (OUT) is obtained at the inverted output of the inverter INV2 and an inverted output (/OUT) is obtained at the inverted output of the inverter INV1.

In the example structure shown in FIG. 5, a non-inverted output from a pass gate (L) is connected to an inverted input of an inverter INV2, and an inverted output from the pass gate circuit (L) is connected to an inverted input of the inverter INV1. Further, an inverted output of the inverter INV2 is connected to a non-inverted input of the inverter INV1 and an inverted output of the inverter INV1 is connected to a non-inverted input of the inverter INV2.

Accordingly, a non-inverted output (OUT) is obtained at the inverted output of the inverter INV2 and an inverted output (/OUT) is obtained at the inverted output of the inverter INV1, and when the pass gate circuit (L) turns off, the state at this time is latched.

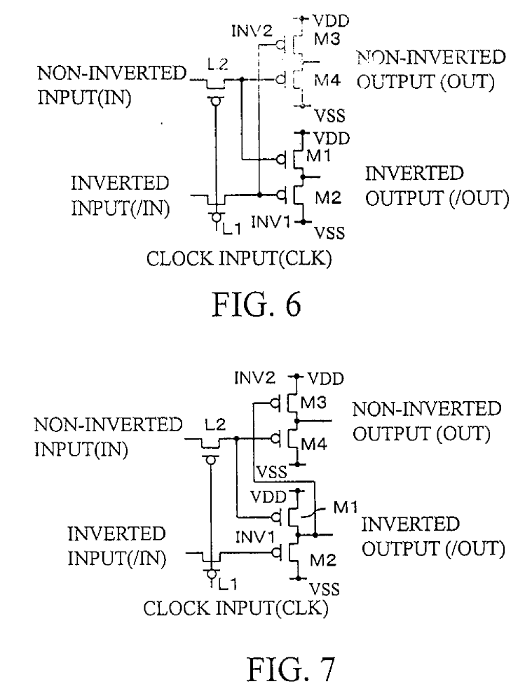

FIG. 6 shows an example circuit structure of the 2-input 2-output type clocked inverter (2-2cINV) shown in FIG. 3A. As shown, the pass gate L is composed of two pass transistors (L1 and L2), and the inverter INV1 is formed of PMOS transistors M1 and M2 which are connected in series between a positive power source VDD and a negative power source VSS, and the inverter INV2 is formed of PMOS transistors M3 and M4 which are connected in series between a positive power source VDD and a negative power source VSS. In this example, an input terminal of the pass transistor (L2) functions as a non-inverted input (IN) of the latch circuit 12 and an input terminal of the pass transistor (L1) functions as an inverted input (/IN) of the latch circuit 12.

A non-inverted input signal and an inverted input signal are input to the input terminals of the two pass transistors (L1, L2), respectively. The output terminal of the pass transistor (L2) is connected to a gate of the transistor M4 located on the lower side of the inverter INV2 and a gate of the transistor M1 located on the upper side of the inverter INV1, and the output terminal of the pass transistor (L1) is connected to a gate of the transistor M3 located on the upper side of the inverter INV2 and a gate of the transistor M2 located on the lower side of the inverter INV1. Therefore, when the input and output of the pass transistor L1 are at H level and the input and output of the pass transistor L2 are at L level, the transistors M2 and M3 turn ON and the transistors M1 and M4 turn OFF, and a signal of L level is output from a middle point between the transistors M1 and M2 of the inverter INV1 (i.e. the output terminal of the inverter INV1) and a signal of H level is output from a middle point between the transistors M3 and M4 of the inverter INV2 (i.e. the output terminal of the inverter INV2). Accordingly, the output terminal of the inverter INV1 functions as an inverted output (/OUT) of the latch circuit 12 and the output terminal of the inverter INV2 functions as a non-inverted output (OUT) of the latch circuit 12.

FIG. 7 shows an example circuit structure of a 2-input 2-output type clocked inverter (2-2cINV) equivalent to the example structure shown in FIG. 4A.

An output terminal of a pass transistor (L2) is connected to a gate of a transistor M4 of an inverter INV2 and a gate of a transistor M1 of an inverter INV1. Further, an output terminal of a pass transistor (L1) is connected to a gate of a transistor M2 of the inverter INV1. In addition, a connection point between the transistors M1 and M2 is connected to a gate of a transistor M3. Accordingly, when the input and output of the pass transistor L1 are at H level and the input and output of the pass transistor L2 are at L level, the transistor M2 turns ON and the transistors M1 and M4 turn OFF. As a result, the output of the inverter INV1 turns to L level and the transistor M3 turns ON. Thus, the output terminal of the inverter INV1 serves as an inverted output (/OUT) of the latch circuit 12 and the output terminal of the inverter INV2 serves as a non-inverted output (OUT).

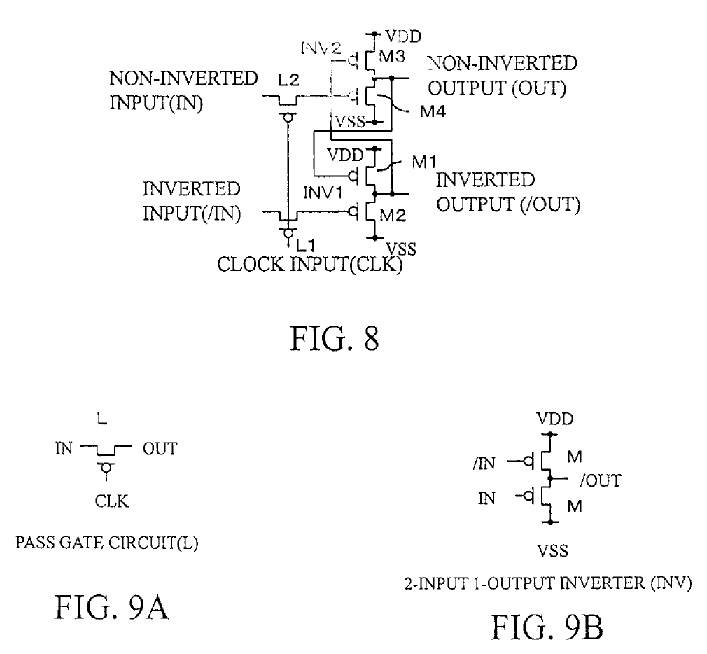

FIG. 8 shows an example circuit structure of a 2-input 2-output type clocked inverter (2-2cINV) in the example structure shown in FIG. 5.

An output terminal of a pass transistor (L2) is connected to a gate of a transistor M4 of an inverter INV2, and an output terminal of a pass transistor (L1) is connected to a gate of a transistor M2 of the inverter INV1. In addition, a connection point between the transistors M1 and M2 is connected to a gate of a transistor M3, and a connection point between the transistors M3 and M4 is connected to a gate of a transistor M1. Accordingly, when the input and output of the pass transistor L1 are at H level and the input and output of the pass transistor L2 are at L level, the transistor M2 turns ON and the transistor and M4 turn OFF. As a result, the output of the inverter INV1 turns to L level and the output of the inverter INV2 turns to H level. Also, the transistor M3 turns ON and the transistor M1 turns OFF. Thus, a state in which the output of the inverter INV1 is at L level and the output of the inverter INV2 is H level is latched.

Depending on the output load of each latch circuit forming a shift register circuit, it can be necessary to increase the number of stages of 2-input 1-output inverters to thereby reduce the output impedance. FIG. 4B shows an example circuit structure in which the number of stages of 2-input 1-output inverters forming the latch circuit shown in FIG. 4A is n. In FIG. 4B, the inverted output and the non-inverted output of each 2-input 2-output inverter are cascade-connected to the inverted output and the non-inverted output of the 2-input 2-output inverter in the following stage. This 2-input 2-output output inverter structure can be similarly formed of the two 2-input 1-output inverters in the example circuit structures shown in FIGS. 3A and 5. Further, while, in the structure shown in FIG. 4B, the number of stages of the 2-input 1-output inverters is an even number, the number of stages can be an odd number.

FIGS. 9A and 9B show structures of a pass gate circuit (L) and a 2-input 1-output inverter, respectively. As shown, the pass gate (L) is composed of one PMOS transistor. The 2-input 1-output inverter can be obtained by arranging two PMOS transistors between a positive power source VDD and a negative power source VSS.

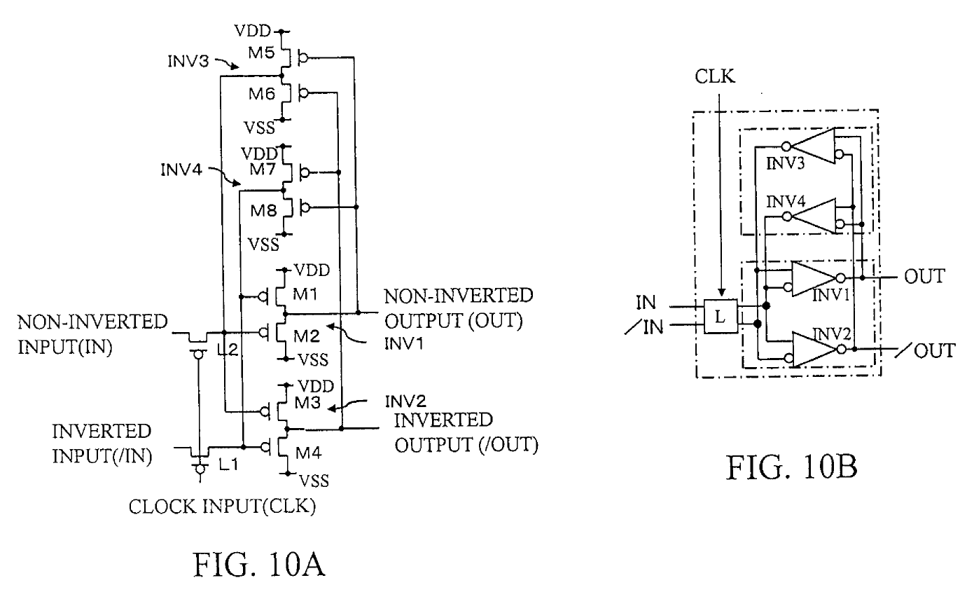

FIG. 10A shows another example structure of a 2-input 2-output type clocked inverter (2-2cINV). As shown in FIG. 10B, this example structure includes four 2-input 1-output inverters INV1 to INV4. The two inverters INV1 and INV2 correspond to the inverters shown in FIG. 3A. The output of the inverter INV1 is connected to a non-inverted input of the inverter INV3 and an inverted input of the inverter INV4, and the output (inverted output) of the inverter INV2 is connected to a non-inverted input of the INV 4 and an inverted input of the inverter INV3. Further, the output (inverted output) of the inverter INV3 is connected to a non-inverted input terminal of the inverter INV1 and an inverted input terminal of the inverter INV2, and the output (inverted output) of the inverter INV4 is connected to an inverted input of the INV1 and a non-inverted input of the inverter INV2. Accordingly, the output terminal of the inverter INV1 serves as a non-inverted output (OUT) and the output terminal of the inverter INV2 serves as an inverted output (/OUT).

FIG. 10A shows a circuit corresponding to the structure shown in FIG. 10B. As shown, each of the inverters INV1 to INV4 is formed of two PMOS transistors (M1, M2), (M3, M4), (M5, M6), (M7, M8) connected in series between the positive power source VDD and the negative power source VSS. The non-inverted input (IN) is connected, via the pass transistor L2, to a gate of the transistor M2 of the inverter INV1 and a gate of the transistor M3 of the inverter INV2. The inverted input (/IN) is connected, via the pass transistor L1, to a gate of the transistor M1 of the inverter INV1 and a gate of the transistor M4 of the inverter INV2. Accordingly, the output terminal of the inverter INV1 servers as a non-inverted output (OUT), and the output terminal of the inverter INV2 serves as an inverted output (/OUT). Also, the non-inverted output (OUT) is connected to a gate of the transistor M5 of the inverter INV3 and a gate of the transistor M8 of the inverter INV4, and the inverted output (/OUT) is connected to a gate of the transistor M6 of the inverter INV3 and a gate of the transistor M7 of the inverter INV4. Further, the output of the inverter INV3 is connected to a gate of the transistor M2 of the inverter INV1 and a gate of the transistor M3 of the inverter INV2. Consequently, the inverter INV3 outputs a non-inverted output signal and the inverter INV4 outputs an inverted output signal and these output signals are input to the inverters INV1 and INV2 as a non-inverted input signal and an inverted input signal, respectively. Accordingly, a positive feedback loop is formed concerning the inverters INV1 to INV4, so that the input signals are latched.

As such, in the circuit shown in FIG. 10A, the pass transistors L1 and L2 transmit or block an inverted input signal and a non-inverted input signal in synchronization with a clock signal input to the gates (control outputs) of the pass transistors L1 and L2. Further, two signals, that are an inverted signal and a non-inverted signal, output from the two pass transistors L1 and L2, are input to the 2-input 2-output inverter composed of two 2-input 1-output inverters INV1 and INV2. The 2-input 2-output inverter outputs two signals that are a non-inverted signal and an inverted signal.

The inverters INV3 and INV4 also form a 2-input 2-output inverter circuit having inverted and non-inverted inputs which are connected with the inverted and non-inverted outputs of the 2-input 2-output inverter circuit composed of the inverters INV and INV2. As such, the non-inverted and inverted inputs of the second 2-input 2-output inverter circuit composed of the inverters INV3 and INV4 are connected with the inverted and non-inverted outputs of the 2-input 2-output inverter circuit composed of the inverters INV1 and INV2, respectively, so that a double positive feedback loop concerning the inverted and non-inverted signals is formed within the latch circuit 12.

While the 2-input 2-output inverter shown in FIG. 10B is formed by a structure of the two 2-input 1-output inverters shown in FIG. 3A, the 2-input 2-output inverter shown in FIG. 10B can operate in a similar manner if the structure of the 2-input 2-output inverter shown in FIG. 4A or FIG. 5 is used, although the detailed description thereof will be omitted here.

Here, while all the transistors in the circuits in the above examples are PMOS transistors, even if these PMOS transistors are replaced with NMOS transistors, the circuits can perform in completely the same manner simply with inversion of voltage polarities.

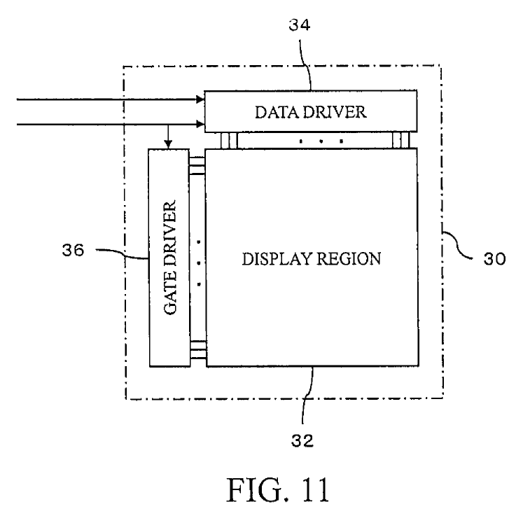

Further, the shift register described above is suitable for an organic EL display device, a liquid crystal display device, and so on. Specifically, in an active matrix display device, a switching transistor is provided in each pixel, and a shift register is used for writing data in each pixel via this switching transistor. For example, FIG. 11 shows an example organic EL panel. The display panel 30 includes a display region 32 in which pixels are arranged in a matrix. Each pixel includes, for example, a switching transistor, a driving transistor, a storage capacitor, and an organic EL element.

Data of each pixel and a pixel clock is supplied to a data driver 34, which sequentially supplies data to a data line provided for each column. On the other hand, a horizontal synchronization signal is supplied to a gate driver 36 for sequentially activating a gate line corresponding to a row to be displayed.

With the above structure and operation, in each pixel, the switching transistor is turned ON by a signal on the gate line, the data on the data line is written in the storage capacitor, and an electric current in accordance with the written data is supplied, via the driving transistor, to the organic EL element, which then emits light in accordance with the data.

The data driver 34 supplies data to the data line sequentially one by one. Because data of each pixel is supplied as one video signal, a switch is required for connecting the video signal line to each data line, and a shift register is normally used for controlling the switch. More specifically, a selection signal is sent to the shift register in accordance with the pixel clock for controlling the ON operation of the switch. The shift register is also used when the gate driver 36 activates the gate line one by one. As such, the shift registers are required for the data driver 34 and the gate driver 36 in a display device. As such shift registers, the shift register according to the present embodiment described above can be preferably adopted. In particular, when the data driver 34 and the gate driver 36 are formed on the display panel 30 in the same process as the switching transistors of the pixels, according to the present embodiment, the shift registers can be formed of only either PMOS transistors or NMOS registers. Consequently, a process of manufacturing the display panel 30 in which the driver sections are formed simultaneously with formation of the pixel sections can be simplified, so that cost reduction can be achieved.

With the achievement of high definition displays, it is demanded that the shift registers operate stably at high frequencies. In the circuit structures shown in FIGS. 6 to 8, for example, the switching speed of the PMOS transistors M2 and M4 which are connected on the lower side (the VSS side) determines the operation frequency of the corresponding shift register. Accordingly, it is desirable to design a circuit such that when a L level signal is input to the gate terminals of the M2 and M4 and a L level signal is output at the source-side outputs of M2 an M4, due to bootstrap caused by gate-source capacitance of the transistors M2 and M4, the gate potential of M2 and M4 is decreased below VSS and the transistors M2 and M4 operate in a linear region. Further, in the circuit structures shown in FIGS. 6 to 8, because the latched signal level is held by blocking the pass gate circuits L1 and L2, it is desirable that parasitic capacitance connected to the gates of the transistors M2 and M4 is sufficiently larger than the leakage current of the pass gate circuits L1 and L2. In order to achieve this, capacitor components can be added between the gate and source of the transistors M2 and M4 or the transistor size of M2 and M4 can be made sufficiently larger than that of the pass gate circuits L1 and L2. On the other hand, in order to perform switching at high frequencies, it is necessary for the pass gate circuits L1 and L2 to have switching abilities sufficient to enable high-speed charge of the capacitor around the gates of the transistors M2 and M4.

With regard to the circuit structure shown FIG. 7, preferable design conditions will be obtained. A condition required for the transistors M2 and M4 to operate in a linear region by bootstrap due to the gate-source capacitance of the transistors M2 and M4 is as follows:

Cgs/Call·ΔV>(α+β)ΔV (1)

Thereafter, a condition for holding the linear region operation condition of the transistors M2 and M4 during the L level output period is as follows:

αΔV−IoffΔT/Call>0 (2)

Further, a condition required for performing switching of L1 and L2 at a sufficiently high speed within a selected period is as follows:

CallΔV/Ion<γΔT (3)

In the above expressions, the gate-source capacitance of M2 or M4 is denoted by Cgs, a sum of all the capacitors connected to the gate terminals is denoted by Call, the ON current and OFF current per unit channel width and unit channel length of L1 and L2 are denoted by Ion and Ioff, respectively, the clock signal voltage amplitude is denoted by ΔV, and the L level signal holding time of a latch circuit forming a shift register is denoted by ΔT. Further, α, β, and γ are design parameters which are real numbers between 0 and 1.

The above conditions (1) to (3) can be rewritten by using a ratio of the channel width and the channel length of each transistor as the following conditions (4) to (6), respectively.

(WL)M2i>(β+α)/(1−β−α)·{(WL)Li+(WL)M(2i−1)} (4)

(WL)Li<1/{IoffΔT/(Lcĥ2αCoxΔV)−1}·{(WL)M2i+(WL)M(2i−1)} (5)

(WL)Li>1/{μα2ΔVγΔT/(2Lcĥ2)−1}·{(WL)M2i+(WL)M(2i−1)} (6)

In the above conditions, the gate capacitance per unit area of the transistor is denoted by Cox, the mobility of the transistor is denoted by μ, the channel areas of Mi (i=1, 2, 3, 4) and Lj(j=1, 2) are denoted by (WL)Mi and (WL)Li, respectively, and the channel length of Li is denoted by Lch.

As a result of calculation of the above expressions with an appropriate value being assigned to each parameter, a preferable condition for operating this circuit can be obtained as follows:

(WL)M2i>1.5*{(WL)Lj+(WL)M(2i−1)} (7)

(WL)Lj<0.0013*{(WL)M2i+(WL)M(2i−1)} (8)

It is preferable that the above condition (7) is satisfied for both transistors M2 and M4 and that the above condition (8) is satisfied for at least one of the pass gate circuits L1 and L2.

Accordingly, from FIG. 7, it is preferable that the following conditions are satisfied:

1.5*(WL)L1<(WL)M2<750*(WL)L1 (9)

1.5*{(WL)L2+(WL)M1}<(WL)M4<750*{(WL)L2+(WL)M1} (10)

Specifically, it is preferable that (WL)M2 is set between 1.5 times and 750 times (WL)L1 and that (WL)M4 is set between 1.5 times and 750 times a sum of (WL)L2 and (WL)M1.

When 2-input 1-output inverters are provided in multiple stages of 2 stages or greater as shown in FIG. 4B, concerning n=1, 2, 3, . . . , similar conditions can be obtained as follows:

1.5*{(WL)M(4n−3)+(WL)M(4n−2)+(WL)M(4n−1)}<M(4n+2)<750*M(4n−2)−{(WL)M(4n−3)+(WL)M(4n−1)} (11)

1.5*{(WL)M(4n−1)+(WL)M(4n)+(WL)M(4n+1)}<M(4n+4)<750*M(4n)−{(WL)M(4n−1)+(WL)M(4n+1)} (12)

Similarly, with regard to the circuit structure shown in FIG. 6, it is preferable that following conditions are satisfied:

1.5*{(WL)L1+(WL)M3}<(WL)M2<750*{(WL)L1+(WL)M3} (13)

1.5*{(WL)L2+(WL)M1}<(WL)M4<750*{(WL)L2+(WL)M1} (14)

1.5*{(WL)M(4n−3)+(WL)M(4n−2)+(WL)M(4n+3)}<(WL)M(4n+2)<750*{(WL)M(4n−2)+(WL)M(4n−3)+(WL)M(4n+3)} (15)

1.5*{(WL)M(4n−1)+(WL)M(4n)+(WL)M(4n+1)}<(WL)M(4n+4)<750*{(WL)M(4n)+(WL)M(4n−1)+(WL)M(4n+1)} (16)

With regard to the circuit structure shown in FIG. 8, it is preferable that the following conditions are satisfied:

1.5*(WL)L1<(WL)M2<750*(WL)L1 (17)

1.5*(WL)L2<(WL)M4<750*(WL)L2 (18)

1.5*{(WL)M(4n−3)+(WL)M4n−2)+(WL)M(4n−1)}<(WL)M(4n+2)<750*{(WL)M(4n−2)+(WL)M(4n−3)+(WL)M(4n−1)} (19)

1.5*{(WL)M(4n−3)+(WL)M(4n−1)+(WL)M(4n)}<(WL)M(4n+2)<750*{(WL)M(4n)+(WL)M(4n−3)+(WL)M(4n−1)} (20)

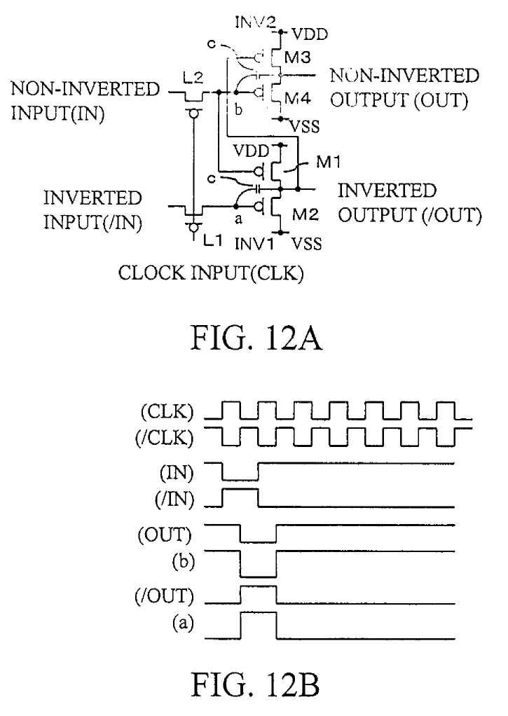

FIG. 12A shows a structure obtained by adding to the structure shown in FIG. 7 capacitor c (which can be parasitic capacitance) between gate and source of each of the transistors M2 and M4. Further, FIG. 12B shows signal waveforms of clocks CLK, /CLK, inputs IN, /IN, outputs OUT, /OUT, and the gates (a) and (b) of transistors M2 and M4. Due to the gate-source capacitance of the transistors M2 and M4, it is possible to maintain the level of the output signals OUT and /OUT even if L1 and L2 are turned OFF.

The invention has been described in detail with particular reference to certain preferred embodiments thereof, but it will be understood that variations and modifications can be effected within the spirit and scope of the invention.

Parts List

| | |
|---|---|
| 1 | clock signal |
| 2 | clock signal |
| 7 | condition |
| 8 | condition |
| 10 | shift register |
| 12 | latch circuit |
| 30 | display panel |
| 32 | display region |
| 34 | data driver |
| 36 | gate driver |

1. A shift register responsive to a non-inverted input signal, an inverted input signal, and first and second clock signals, comprising:
(a) a first and a second latch circuit, each including an inverted signal input, a non-inverted signal input, an inverted signal output, a non-inverted signal output, and a control input;
(b) the non-inverted input signal is connected to the non-inverted signal input of the first latch circuit, the inverted input signal is connected to the inverted signal input of the first latch circuit;
(c) the inverted signal output of the first latch circuit is connected to the one of the inverted signal input or the non-inverted signal input of the second latch circuit, and wherein the non-inverted signal output of the first latch circuit is connected to one of the non-inverted signal input or the inverted signal input of the second latch circuit and wherein the non-inverted signal output and the inverted signal output of the first latch circuit are connected to different signal inputs of the second latch circuit;
(d) the first clock signal is connected to the control input of the first latch circuit and the second clock signal is connected to the control input of the second latch circuit; and
(e) the first clock signal has a first phase and the second clock signal has a second phase different from the first phase.

2. The shift register according to claim 1, wherein the first phase and the second phase are opposite with respect to each other.

3. The shift register according to claim 1, wherein the inverted signal output of the first latch circuit is connected to the non-inverted signal input of the second latch circuit, and wherein the non-inverted signal output of the first latch circuit is connected to the inverted signal input of the second latch circuit.

4. The shift register according to claim 1, wherein each latch circuit includes:
(i) a pass gate circuit having an inverted signal input connected to the inverted signal input of the latch circuit, a non-inverted signal input connected to the non-inverted signal input of the latch circuit, and a control input connected to the control input of the latch signal, and having a non-inverted output and an inverted output; and
(ii) a first inverter circuit having a non-inverted signal input connected to the non-inverted signal output of the pass gate circuit, an inverted signal input connected to the inverted signal output of the pass gate circuit, and having a non-inverted signal output connected to the non-inverted signal output of the of the latch circuit, and an inverted signal output connected to the inverted signal output of the latch circuit.

5. The shift register according to claim 4, wherein the pass gate circuit and the first inverter circuit include corresponding transistors, and wherein the corresponding transistors include P-type TFTs.

6. The shift register according to claim 4, further including a first and a second power source,
wherein the pass gate circuit includes a first and a second pass gate circuit transistors, each having a gate terminal, an input terminal, and an output terminal, wherein each gate terminal is connected to the control input of the pass gate circuit, the input terminal of the first pass gate circuit transistor is connected to the non-inverted signal input of the pass gate circuit, the output terminal of the first pass gate circuit transistor is connected to the non-inverted signal output of the pass gate circuit, the input terminal of the second pass gate circuit transistor is connected to the inverted signal input of the pass gate circuit, and the output terminal of the second pass gate circuit transistor is connected to the non-inverted signal output of the pass gate circuit;
and wherein the first inverter circuit includes:
(i) a first inverter circuit transistor having a gate connected to the non-inverted signal input of the first inverter circuit, and a first terminal and a second terminal connected to the first power source and the inverted output of the first inverter circuit, respectively;
(ii) a second inverter circuit transistor having a gate connected to the inverted signal input of the first inverter circuit, and a first terminal and a second terminal connected to the second power source and the inverted output of the first inverter circuit, respectively;
(iii) a third inverter circuit transistor having a gate connected to the inverted signal input of the first inverter circuit, and a first terminal and a second terminal connected to the first power source and the non-inverted output of the first inverter circuit, respectively; and
(iv) a fourth inverter circuit transistor having a gate connected to the non-inverted signal input of the first inverter circuit, and a first terminal and a second terminal connected to the second power source and the non-inverted output of the first inverter circuit, respectively.

7. The shift register according to claim 6, wherein the first and second pass gate transistors and the first, second, third and fourth inverter circuit transistors are all P-Type TFTs or all N-Type TFTs.

8. The shift register according to claim 6,
wherein M2 and M4 are the second and fourth inverter circuit transistors, respectively, and L1 and L2 are the first and second pass gate circuit transistors, respectively, and (WL)Mi and (WL)Li are channel areas of Mi (i=2, 4) and Lj(j=1, 2), respectively;
wherein:
1.5*(WL)L1<(WL)M2, and
1.5*(WL)L2<(WL)M4; and
wherein:
(WL)M2<750*(WL)L1, or
(WL)M4<750*(WL)L2.
